(19) United States
(12) Patent Application Publication
(10) Pub. No.: US 2021/0333702 A1
(43) Pub. Date: Oct. 28, 2021

(54) Substrate with Film for Reflective Mask Blank, and Reflective Mask Blank

(71) Applicant: Shin-Etsu Chemical Co., Ltd., Tokyo (JP)

(72) Inventors: Tsuneo TERASAWA, Joetsu-shi (JP); Hideo KANEKO, Joetsu-shi (JP); Yukio INAZUKI, Joetsu-shi (JP); Takuro KOSAKA, Joetsu-shi (JP)

(73) Assignee: Shin-Etsu Chemical Co., Ltd., Tokyo (JP)

(21) Appl. No.: 17/224,673

(22) Filed: Apr. 7, 2021

(30) Foreign Application Priority Data
Apr. 28, 2020 (JP) 2020-079089

(51) Int. Cl. G03F 1/24; G03F 1/58; H01L 21/033

(52) U.S. Cl. CPC G03F 1/24; H01L 21/0332; H01L 21/0337; G03F 1/58

(57) ABSTRACT

A substrate with a film for a reflective mask blank and a reflective mask blank, including a substrate, a multilayer reflection film of Mo layers and Si layers, and a Ru protection film is provided. The substrate and blank include a mixing layer containing Mo and Si existing between the Mo layer and Si layer, another mixing layer containing Ru and Si generating between the uppermost Si layer and the Ru protection film, the film and layers have thicknesses satisfying defined expressions.

### CROSS-REFERENCE TO RELATED APPLICATION

This non-provisional application claims priority under 35 U.S.C. § 119(a) on Patent Application No. 2020-79089 filed in Japan on Apr. 28, 2020, the entire contents of which are hereby incorporated by reference.

### TECHNICAL FIELD

The present invention relates to a reflective mask blank for manufacturing a reflective mask used for manufacturing semiconductor devices, and a substrate with a film for a reflective mask blank in which decrease in reflectance is suppressed even if a protection film is provided on a multilayer reflection film.

### BACKGROUND ART

In a manufacturing process of semiconductor devices, a photolithography technique in which a circuit pattern formed on a transfer mask is transferred onto a semiconductor substrate (semiconductor wafer) through a reduction projection optical system with irradiating exposure light to the transfer mask is repeatedly used. Conventionally, a mainstream wavelength of the exposure light is 193 nm by argon fluoride (ArF) excimer laser light. A pattern with dimensions smaller than exposure wavelength has finally been formed by adopting a process called multi-patterning in which exposure processes and processing processes are combined multiple times.

However, since it is necessary to form a further fine pattern under continuous miniaturization of device patterns, EUV lithography technique using, as exposure light, extreme ultraviolet (hereinafter referred to “EUV”) light having a wavelength shorter than ArF excimer laser light is promising. EUV light is light having a wavelength of about 0.2 to 100 nm, more specifically, light having a wavelength of around 13.5 nm. This EUV light has a very low transparency to a substance and cannot be utilized for a conventional transmissive projection optical system or a mask, thus, a reflection type optical elemental device is applied. Therefore, a reflective mask is also proposed as a mask for the pattern transfer.

The reflective mask has a multilayer reflection film that is formed on a substrate and reflects EUV light, and a patterned absorber film that is formed on the multilayer reflection film and absorbs EUV light. Meanwhile, a material (including a material in which a resist film is formed) before patterning the absorber film is called a reflective mask blank, and is used as a material for the reflective mask. Hereinafter, a reflective mask blank that reflects EUV light is also referred to as an EUV mask blank. The EUV mask blank has a basic structure including a multilayer reflection film that is formed on a glass substrate and reflects EUV light, and an absorber film that is formed thereon and absorbs EUV light. As the multilayer reflection film, a Mo/Si multilayer reflection film which is ensured a reflectance for EUV light by alternately laminating molybdenum (Mo) layers and silicon (Si) layers is usually used. On the other hand, as the absorber film, a material containing tantalum (Ta) or chromium (Cr) as a main component, which has a relatively large extinction coefficient with respect to EUV light, is used.

A protection film is formed between the multilayer reflection film and the absorber film to protect the multilayer reflection film. The protection film is provided for the purpose of protecting the multilayer reflection film to avoid damages of the multilayer reflection film in a step such as an etching for the purpose of forming a pattern to the absorber film, a pattern repair process for detected defects after forming the pattern, and a cleaning the mask after forming the pattern. For the protection film, ruthenium (Ru) or a material containing Ru as a main component as disclosed in JP-A 2002-122981 (Patent Document 1) or JP-A 2005-268750 (Patent Document 2) is used. A thickness of the protection film is preferably 2.0 to 2.5 nm from the viewpoint of ensuring reflectance, however, is preferably at least 3 nm from the viewpoint of protecting the multilayer reflection film.

### CITATION LIST

Patent Document 1: JP-A 2002-122981
Patent Document 2: JP-A 2005-268750

### SUMMARY OF THE INVENTION

A multilayer reflection film in which Mo layers and Si layers are alternately laminated can obtain a relatively high reflectance of about 66 to 68% with respect to EUV light. However, when a Ru film as a protection film is formed on the multilayer reflection film, the reflectance of EUV light irradiated to the surface of the protection film is decreased 1.5 to 3% as a difference although it depends on the thickness of the protection film. This decrease in reflectance tends to progress further in steps of manufacturing a reflective mask and in a step of exposing with EUV light. As described above, it is concerned that the reflectance of the multilayer reflection film is lowered due to the formation of the protection film.

The present invention has been made to solve the above problems, and an object of the present invention is to provide a reflective mask blank and a substrate with a film for a reflective mask blank that can realize a reflective mask having a good transferability, and has a multilayer reflection film in which decrease in reflectance of the multilayer reflection film due to formation of a protection film is suppressed, and is ensured a high reflectance for EUV light for a long period also after processed into the reflective mask or exposure using the reflective mask.

With respect to a multilayer reflection film and a protection film in a reflective mask blank for reflecting EUV light (an EUV mask blank), the inventors have been studied reflectance by repeated calculations with utilizing simulation. As a result, as a substrate with a film for a reflective mask blank including a multilayer reflection film including molybdenum (Mo) layers and silicon layers (Si) alternately laminated with an uppermost silicon (Si) layer, and a protection film containing ruthenium (Ru) as a main component and formed contiguous to the uppermost silicon (Si) layer, further, as a reflective mask blank including the substrate with a film for a reflective mask blank with an absorber film and a conductive film, the inventors have been found that a substrate with a film for a reflective mask blank and a reflective mask blank in which one mixing layer containing Mo and Si is generated at one boundary portion between the molybdenum (Mo) layer and the silicon (Si) layer, and another mixing layer containing Ru and Si is generated at another boundary portion between the uppermost silicon (Si) layer and the protection film, and in which thicknesses of the film and layers defined below satisfy all of the following expressions (1) to (3):

5.3≤T_{upSi}+T_{RuSi}+T_{Ru}/2≤5.5 (1)

1.1≤T_{Ru}/2−(T_{Si}−T_{upSi})≤1.3 (2)

3.0≤T_{Ru}≤4.0 (3)

wherein T_{Ru} (nm) represents a thickness of the protection film, T_{RuSi} (nm) represents a thickness of said another mixing layer at said another boundary portion between the uppermost silicon (Si) layer and the protection film, T_{upSi} (nm) represents a thickness of the uppermost silicon (Si) layer exclusive of the mixing layers, and T_{Si} (nm) represents a thickness of the silicon (Si) layer exclusive of the mixing layers in the periodic laminated structure below the uppermost silicon (Si) layer. The substrate with a film for a reflective mask blank and the reflective mask blank have a high initial EUV light reflectance, and decrease in reflectance of the multilayer reflection film due to the protection film is suppressed. Further, even when the protection film is existed, as a reflectance of EUV light irradiated from the surface side of the protection film, a high reflectance can be maintained. Furthermore, in EUV lithography, in case of assuming the mask with 4× magnification under the condition of NA=0.33, an incident angle of EUV light to the reflective mask should be considered in a range of 6±4.7° (1.3 to 10.7°). The inventive multilayer reflection film and protection film can be ensured a high reflectance in the incident angle range of 1.3 to 10.7°.

A mixing layer containing Ru and Si is generated as a Ru/Si mixing layer at a boundary portion of both layers when the Ru layer is formed on the Si layer. Herein, the mixing layer containing Ru and Si is distinguished from the Ru layer and the Si layer. Meanwhile, a mixing layer is also generated as a Mo/Si mixing layer at a boundary portion of a Mo layer and a Si layer. Both mixing layers can be observed on the cross-section, for example, by TEM, and thicknesses can be also measured.

In one aspect, the invention provides a substrate with a film for a reflective mask blank including a substrate, a multilayer reflection film that is formed on a main surface of the substrate and reflects extreme ultraviolet (EUV) light, and a protection film that is formed contiguous to the multilayer reflection film, wherein

the multilayer reflection film has a periodic laminated structure in which molybdenum (Mo) layers and silicon layers (Si) are alternately laminated with an uppermost silicon (Si) layer, and one mixing layer containing Mo and Si exists at one boundary portion between the molybdenum (Mo) layer and the silicon (Si) layer,

the protection film contains ruthenium (Ru) as a main component, and another mixing layer containing Ru and Si is generated at another boundary portion between the uppermost silicon (Si) layer and the protection film, and

thicknesses of the film and layers defined below satisfy all of the following expressions (1) to (3):

5.3≤T_{upSi}+T_{RuSi}+T_{Ru}/2≤5.5 (1)

1.1≤T_{Ru}/2−(T_{Si}−T_{upSi})≤1.3 (2)

3.0≤T_{Ru}≤4.0 (3)

wherein T_{Ru} (nm) represents a thickness of the protection film, T_{RuSi} (nm) represents a thickness of said another mixing layer at said another boundary portion between the uppermost silicon (Si) layer and the protection film, T_{upSi} (nm) represents a thickness of the uppermost silicon (Si) layer exclusive of the mixing layers, and T_{Si} (nm) represents a thickness of the silicon (Si) layer exclusive of the mixing layers, in the periodic laminated structure below the uppermost silicon (Si) layer.

Preferably, in the substrate with a film for a reflective mask blank, a minimum reflectance (%) with respect to EUV light at an incident angle in a range of 1.3 to 10.7° satisfies the following expression (4):

Rₘᵢₙ≥72−2×T_{Ru} (4)

wherein T_{Ru} represents a thickness (nm) of the protection film.

In another aspect, the invention provides a reflective mask blank including the substrate with a film for a reflective mask blank, an absorber film that is formed on the protection film and absorbs the extreme ultraviolet (EUV) light, and a conductive layer formed on the opposite main surface of the substrate.

### Advantageous Effects of the Invention

According to the invention, it is possible to realize a substrate with a film for a reflective mask blank in which decrease in reflectance caused by formation of a protection film on a multilayer reflection film is suppressed. Further, by forming an absorber film on the protection film, it can be provided that a highly reliable reflective mask blank in which a prescribed reflectance is ensured with protecting the multilayer reflection film, even after processed into a reflective mask.

### BRIEF DESCRIPTION OF THE DRAWINGS

FIG. 1A is a cross-sectional view of a main portion of a reflective mask blank of the present invention; FIG. 1B is a cross-sectional view of a main portion illustrating a state in which a resist is applied to the surface of the reflective mask blank of FIG. 1A; and

FIG. 1C is a cross-sectional view of a main portion illustrating a state in which the resist film is drawn from the state of FIG. 1B, and then the absorber film is etched to form an absorber film pattern.

FIG. 2 illustrates a state before forming an absorber film in the reflective mask blank of the invention, and is a cross-sectional view of an upper portion of a multilayer reflection film and a protection film thereon.

FIGS. 3A and 3B are graphs illustrating a reflectance of EUV light of a multilayer reflection film of the present invention as a function of a thickness of an uppermost Si layer and a thickness of a mixing layer of Ru and Si at an incident angle of light of 6° (FIG. 3A) and at an incident angle of light of 10° (FIG. 3B), respectively.

FIG. 4 is a graph illustrating an example in which a reflectance R of a multilayer reflection film is calculated as a function with an incident angle θ of EUV light.

FIGS. 5A to 5C are graphs illustrating that a reflectance R of a multilayer reflection film depending on an incident angle θ of EUV light is improved in varying a thickness of an uppermost Si layer, FIG. 5A illustrating calculated values which are assumed a protection film having a thickness of 3.0 nm, FIG. 5B illustrating calculated values which are assumed a protection film having a thickness of 3.5 nm, and FIG. 5C illustrating calculated values which are assumed a protection film having a thickness of 4.0 nm.

FIG. 6 is a flowchart for manufacturing a reflective mask blank of the invention.

### DESCRIPTION OF THE PREFERRED EMBODIMENT

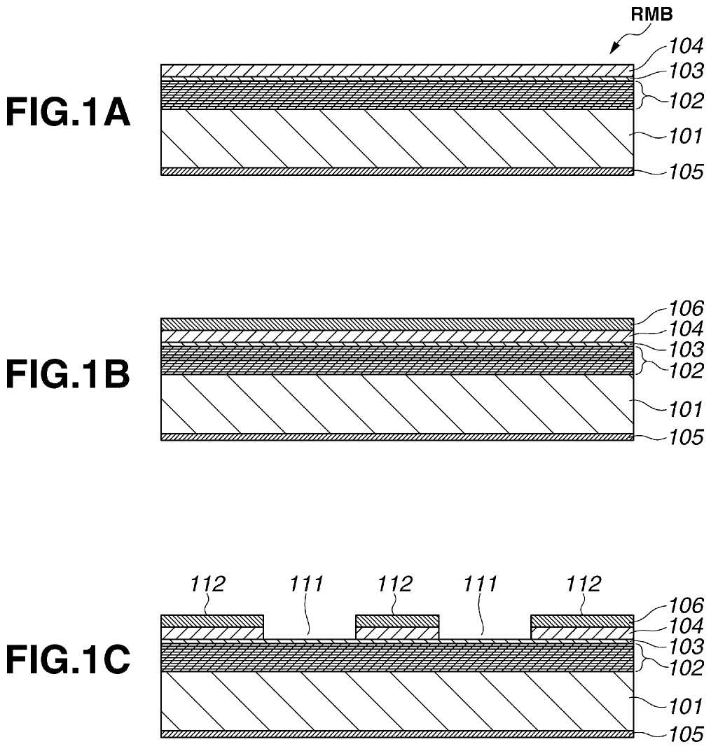

An outline of processes for manufacturing a reflective mask blank and a reflective mask for EUV exposure is illustrated in FIGS. 1A to 1C. FIG. 1A is a cross-sectional view of a main portion of a reflective mask blank RMB. In the reflective mask blank RMB, a multilayer reflection film 102 that reflects EUV light, a protection film 103 for the multilayer reflection film 102, and an absorber film 104 that absorbs the EUV light are formed in this order on a main surface of a substrate 101 composed of a low thermal expansion material that is sufficiently flattened. On the other hand, a conductive film 105 for electrostatically holding the reflective mask on a mask stage of an exposure tool is formed the other main surface (back side surface) of the substrate 101 which is opposite to the main surface on which the multilayer reflection film 102 is formed.

A substrate 101 having a coefficient of thermal expansion within ±1.0×10⁻⁸/C°, preferably ±5.0×10⁻⁹/C° is used. Further, a main surface of the substrate 101 of the side to form an absorber film is surface-processed so as to have high flatness in the region where the absorber pattern is formed, and has a surface roughness RMS of preferably not more than 0.1 nm, more preferably not more than 0.06 nm.

A multilayer reflection film 102 is a multilayer film in which layers of a low refractive index material and layers of a high refractive index material are alternately laminated. For EUV light having an exposure wavelength of 13 to 14 nm, for example, a Mo/Si periodic laminated film in which molybdenum (Mo) layers and silicon (Si) layers are alternately laminated for about 40 cycles is used.

A protection film 103 is also called a capping layer, and is provided to protect the multilayer reflection film 102 when forming a pattern of the absorber film 104 thereon or repairing the pattern. As a material of the protection film 103, silicon is used, and in addition, ruthenium, or a compound containing ruthenium, and niobium or zirconium is also used. A thickness the protection film is in the range of about 2.5 to 4 nm.

FIG. 1B illustrates a state in which a resist is applied to the surface of the reflective mask blank RMB of FIG. 1A. A pattern is drawn to a resist film 106, and a resist pattern is formed by using usual electron beam lithography. Then, the resist pattern is used as an etching mask, and the absorber film 104 thereunder is removed by etching. Thereby, a portion removed by etching 111, and absorber pattern portion 112 consisting of an absorption film pattern and the resist pattern are formed, as illustrated in FIG. 1C. After that, a reflective mask having a basic structure can be obtained by removing the remaining resist film pattern.

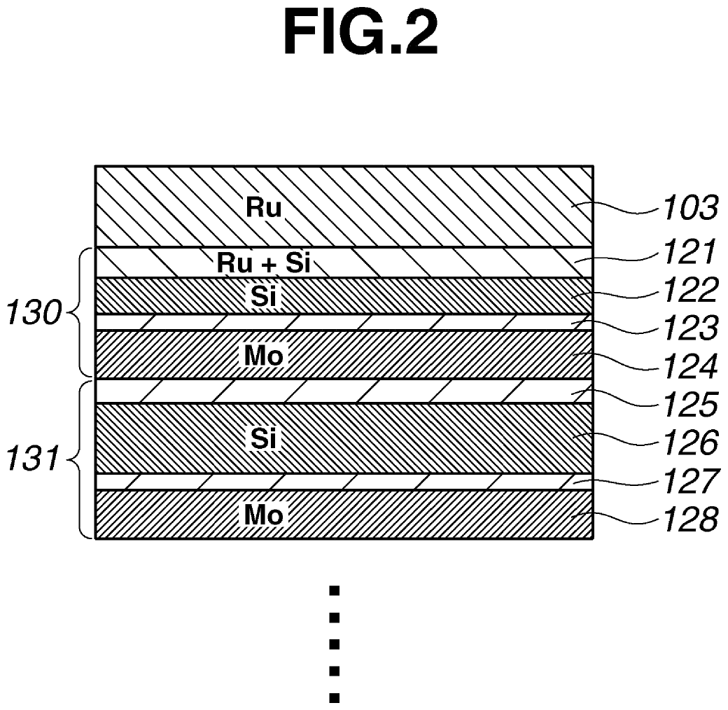

The followings describe a film for a reflective mask blank including a multilayer reflection film that reflects EUV light of the present invention. FIG. 2 illustrates a state of a substrate with a film for a reflective mask blank in which a multilayer reflection film 102 that reflects EUV light and a protection film thereof has been formed on the main surface of the substrate 101, and is a cross-sectional view of an upper portion of the substrate with a film for a reflective mask blank that includes the protection film 103 and the multilayer reflection film 102. In FIG. 2, the symbol “121” represents a mixing layer of Ru which is a main component of the protection film 103 and Si which is a component of the directly-contacted Si layer 122 thereunder, the symbol “126” represents a Si layer, the symbols “124” and “128” represent a Mo layer, and the symbols “123”, “125” and “127” represent a mixing layer of Si and Mo.

Further, the symbol “130” represents a region of a pair of Mo/Si layers including the mixing layer of Ru and Si 121 and the mixing layer of Si and Mo 123, at the uppermost portion of the multilayer reflection film, and the symbol “131” represents a region of a pair of Mo/Si layers including the mixing layers 125, 127 of Si and Mo, under the uppermost pair of Mo/Si layers. Although it is not illustrated in FIG. 2, the same structures of the region of the pair of Mo/Si layers 131 are successively formed under the region of the pair of Mo/Si layers 131.

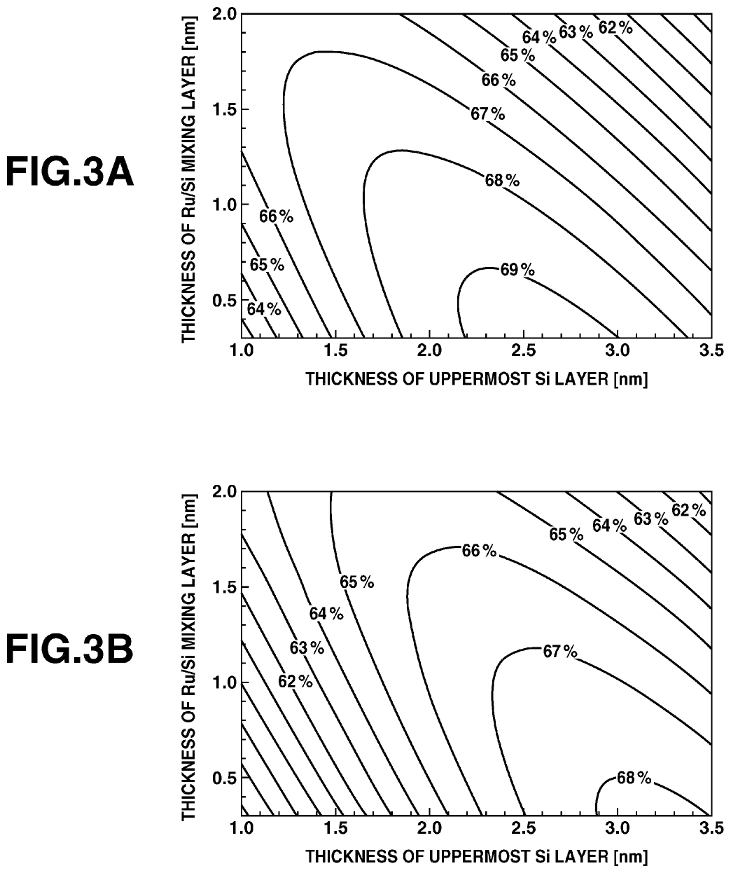

As a thickness (cycle length) of the region of the pair of Mo/Si layers, a thickness of 7.0 to 7.05 nm is normally adopted. Here, to evaluate reflectance of the multilayer reflection film by simulation, a thickness of a mixing layer 125 generated at the interface between Si layer and Mo layer thereon, and a thickness of a mixing layer 127 generated at the interface between Mo layer and Si layer thereon are assumed to 1.2 nm and 0.4 nm, respectively, with reference to many actual measurement results by cross-section TEM observation. As a result, it was confirmed that, when EUV light irradiates to the multilayer reflection film at an incident angle of 6° with respect to the normal of the surface of the multilayer reflection film, the reflectance of the multilayer reflection film after forming the protection film 103 is decreased about 1.5% as a difference, compared with before forming the protection film 103. Actually, when the protection film 103 containing Ru as a main component is formed on the uppermost Si layer 122 thereon, a mixing layer of Ru and Si 121 is generated at the upper surface portion of the uppermost Si layer 122 directly under the protection film 103. A reflectance of the multilayer reflection film was calculated as a function of a thickness of the mixing layer of Ru and Si 121 and a thickness of the uppermost Si layer 122, thereby the result illustrated in FIG. 3A was obtained. Further, the reflectance at an incident angle of 10° was calculated, and the results illustrated in FIG. 3B was obtained.

FIGS. 3A and 3B indicate that a thinner mixing layer of Ru and Si 121 tends to have a higher reflectance. Further, FIGS. 3A and 3B indicate that when the mixing layer 121 has a certain value, an optimal thickness of the uppermost Si layer for maximizing the reflectance can be found. Accordingly, it was found that, in FIGS. 3A and 3B, the following relational expressions:

T1×1.3+T2=3.7 at an incident angle of 6°

T1×1.3+T2=4.5 at an incident angle of 10°

are held between the thickness T2 (nm) of the mixing layer of Ru and Si 121, and the thickness T1 (nm) of the uppermost Si layer 122 that can impart the maximum reflectance.

In other words, the values of T1 and T2 which can impart the maximum reflectance depend to the incident angle. For example, in case that the thickness T2 of the mixing layer of Ru and Si 121 is 1.2 nm, the maximum reflectance can be obtained when the thickness of the uppermost Si layer 122 is 1.9 nm at an incident angle of 6°, and the thickness of the uppermost Si layer 122 is 2.5 nm at an incident angle of 10°. Further, in case that the thickness T2 of the mixing layer of Ru and Si 121 is 1.4 nm, the maximum reflectance can be obtained when the thickness of the uppermost Si layer 122 is 1.8 nm at an incident angle of 6°, and the thickness of the uppermost Si layer 122 is 2.4 nm at an incident angle of 10°.

In actually using a multilayer reflection film in a reflective mask for EUV exposure, EUV light may be incident on the multilayer reflection film at an incident angle range of about 1.3 to 10.7°. Therefore, a combination of the thickness of the mixing layer of Ru and Si and the thickness of the uppermost Si layer is selected so as to obtain the maximum reflectance with respect to the angle. However, since it is unfavorable that the reflectance is extremely lowered at any incident angle, the combination of thicknesses having an equable reflectance distribution and not significantly changing within the incident angle range of 1.3 to 10.7° should be selected.

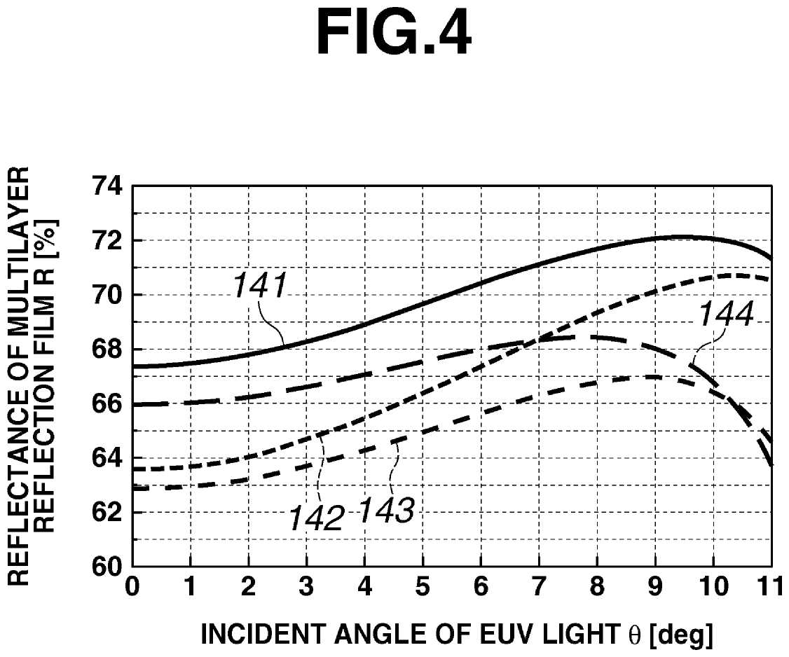

FIG. 4 is a graph illustrating calculation results of dependencies of the EUV light reflectance R on an incident angle θ in a multilayer reflection film. A range of the incident angle of 0 to 11°, and a cycle length of 7.02 nm in the Mo/Si multilayer reflection film were set. In FIG. 4, curve 141 describes a reflectance of the Mo/Si multilayer reflection film (40 pairs) that does not have either of a mixing layer of Ru and Si or a Ru film as a protection film. When a Ru film having a thickness of 3.5 nm is formed thereon, the reflectance decreases as described by curve 142. For example, when the incident angle is 6°, the reflectance is decreased by about 3% as a difference. Further, the reflectance described by curve 143 was obtained by assuming, as thicknesses of the mixing layer in accordance with various experimental results, 0.4 nm-thickness of a mixing layer of the Mo and the component (Si) of the upside layer thereof, and 1.2 nm-thickness of a mixing layer of Si and the component (Mo) of the upside layer thereof. The reflectance described by curve 143 indicates that a reflectance of about 65% can be ensured at an incident angle of 6° or more, however, the reflectance is further decreased to 63% or low at an incident angle of 1.3°. Thus, when the thickness of the uppermost Si layer is reduced by about 0.8 nm, the reflectance described in curve 144 can be obtained. Particularly, the decreased reflectance is recovered to about 66% in a region of the incident angle of not more than 7°. Therefore, an equable reflectance distribution can be ensured by adjusting the thickness of the uppermost Si layer.

The above calculation is based on the assumption in which a thickness of the Ru film acting as a protection film for the Mo/Si multilayer reflection film is 3.5 nm. However, for other thicknesses, the combination of the thicknesses can be selected in the same manner. Specifically, reflectance distribution corresponding to curve 144 in FIG. 4 is obtained by assuming the thickness of the mixing layer of Ru and Si with changing the thickness of the uppermost Si layer. Then, a thickness of the uppermost Si layer that can obtain an equable reflectance distribution within a prescribed range of the incident angle may be selected. In addition, in forming the multilayer reflection film, a designed value of an initial thickness for the Si layer formed as the uppermost layer in the multilayer reflection film or an initial thickness of the Si layer in the periodic laminated structure below the uppermost Si layer may be the sum of the thickness of the mixing layer of Ru and Si and the thickness of the uppermost Si layer, assumed in the simulation.

By using a multilayer reflection film and a protection film that satisfy the above requirements, an initial reflectance can be maintained high over the entire incident angle of EUV light utilized in an EUV mask. Therefore, when an absorber film that absorbs EUV light, for example, an absorber film containing tantalum (Ta) or chromium (Cr) as a main component is formed on the multilayer reflection film, it is possible to provide a reflective mask blank (EUV mask blank) capable of realizing a reflective mask (EUV mask) having high transferability after the absorber film is patterned.

### Example for Embodiment 1

In this embodiment, a Ru film as a protection film formed on a Mo/Si multilayer reflection film was selected. A thickness of the protection film is preferably 2.0 to 2.5 nm in viewpoint for ensuring reflectance, however, the thickness of the protection film was set to at least 3.0 nm in viewpoint for protecting the multilayer reflection film and was set to not more than 4 nm in viewpoint for controlling significant decrease of the reflectance. Accordingly, in this case, the thickness T_{Ru} of the protection film is within a range satisfying the following expression (3):

3.0≤T_{Ru}≤4.0 (3).

The thickness of the Ru film was set to 3.0 nm, 3.5 nm or 4.0 nm, and a structure of the multilayer reflection film which can impart an equable high reflectance distribution within an incident angle of EUV light of 1.3 to 10.7° was determined by simulation.

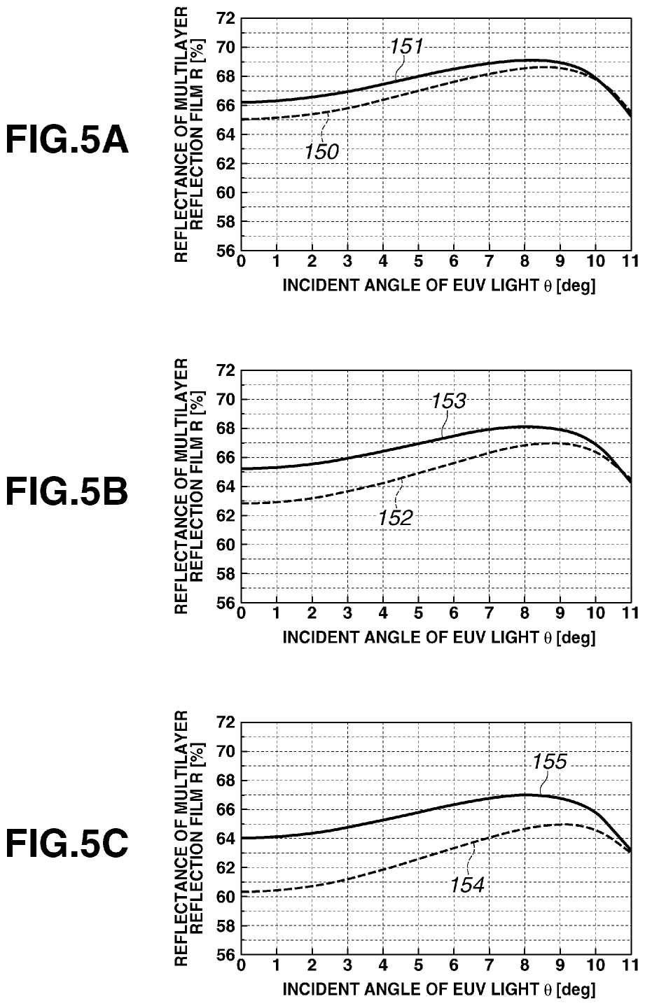

Next, a substrate with a film for an EUV reflective mask blank was manufactured by forming a multilayer reflection film that reflects EUV light and a protection film in this order on a main surface of a substrate composed of a low thermal expansion material. Structures of the multilayer reflection film in which the above-mentioned three kinds of the thicknesses were set to the Ru film are described with reference to FIG. 5 as follows.

First, a cycle length of the Mo/Si multilayer reflection film (40 pairs) was set to 7.02 nm, and thicknesses of the Si layer and Mo layer before generating a mixing layer were set to 4.21 nm and 2.81 nm, respectively. If the mixing layer is not generated, the reflectance is maximized at an incident angle of EUV light of at least 9°, and the reflectance within a range of 1.3 to 10.7° is resulted in unequable distribution as the case mentioned above. However, the mixing layer is practically generated, and the reflectance is significantly decreased within a region of large incident angle. Therefore, the above cycle length was selected as an initial cycle length, and thicknesses of mixing layers were set to 0.4 nm for the mixing layer of Mo and the component (Si) of the upside layer thereof, and 1.2 nm for the mixing layer of Si and the component (Mo or Ru) of the upside layer thereof. Accordingly, thicknesses of Si layer and Mo layer exclusive of the mixing layers are 3.01 nm and 2.41 nm, respectively.

Here, it was assumed that a thickness of the protection film consisting of a Ru film is 3.0 nm. In this case, it was assumed that a mixing layer of Ru and Si having a thickness of 1.2 nm is generated on the upper portion of the uppermost Si layer. In other words, it was assumed that the substantive thickness of the uppermost Si layer is reduced by 1.2 nm compared with the value set for forming the film. The result described by curve 150 in FIG. 5A was obtained by calculating reflectance R of EUV light at an incident angle within an incident angle θ of 1.3 to 10.7°. Here, the reflectance described by curve 151 in FIG. 5A was obtained by reducing the thickness of the uppermost Si layer by 0.3 nm compared with the Si layer in the periodic laminated structure thereunder, i.e., by reducing the thickness set for forming the film by 0.3 nm. In case that an incident angle is narrowed down to a certain value, for example, 6°, the reflectance increases when the uppermost Si layer is formed further thinner. However, the reflectance was decreased within a range of an incident angle of 9° or more, not obtaining an equable reflectance distribution. So, the thickness of the uppermost Si layer was designed by reducing by 0.3 nm compared with the Si layer in the periodic laminated structure thereunder, realizing a reflectance of 66% or more.

Next, a decreased amount of the thickness of the uppermost Si layer (a thickness of a mixing layer of Ru and Si) when the thickness of the protection film consisting of Ru film was assumed to 3.5 nm was calculated. As the same above, it was assumed that a thickness of a mixing layer of Ru and Si is 1.2 nm. The reflectance described by curve 152 in FIG. 5B was obtained when the thickness of the uppermost Si layer was assumed as same as the thickness of the Si layer in the periodic laminated structure thereunder. So, the thickness of the uppermost Si layer was reduced by 0.55 nm compared with the Si layer in the periodic laminated structure thereunder. As a result, the reflectance described by curve 153 in FIG. 5B was obtained, realizing a reflectance of 65% or more within a range of an incident angle of 1.3 to 10.7°.

Further, a decreased amount of the thickness of the uppermost Si layer when the thickness of the protection film consisting of Ru film was assumed to 4.0 nm was calculated. As the same above, it was assumed that a thickness of a mixing layer of Ru and Si is 1.2 nm. The reflectance described by curve 154 in FIG. 5C was obtained when the thickness of the uppermost Si layer was assumed as same as the thickness of the Si layer in the periodic laminated structure thereunder. In this case, the reflectance was significantly decreased in a range of an incident angle of not more than 8°. So, the thickness of the uppermost Si layer was reduced by 0.8 nm compared with the Si layer in the periodic laminated structure thereunder. As a result, the reflectance described by curve 155 in FIG. 5C was obtained, realizing a reflectance of 64% or more within a range of an incident angle of 1.3 to 10.7°.

Accordingly, an equable reflectance distribution was obtained in each case of: setting the decreased amount of 0.3 nm in the thickness of the uppermost Si layer, and the thickness of 3.0 nm in the protection film consisting of Ru film; setting the decreased amount of 0.55 nm in the thickness of the uppermost Si layer, and the thickness of 3.5 nm in the protection film consisting of Ru film; or setting the decreased amount of 0.8 nm in the thickness of the uppermost Si layer, and the thickness of 4.0 nm in the protection film consisting of Ru film. Further, a relation represented by the following expression (4):

Rₘᵢₙ≥72−2×T_{Ru} (4)

was resulted between the thickness T_{Ru} (nm) of the protection film, and the minimum reflectance Rₘᵢₙ (%) with respect to EUV light within a range of an incident angle of 1.3 to 10.7°.

According to the above results, as a relation for realizing an equable reflectance distribution within a range of an incident angle of 1.3 to 10.7°, the following expression

T_{upSi}+T_{RuSi}+T_{Ru}/2≤5.41

was resulted. In this expression, T_{upSi} represents a thickness of the uppermost Si layer exclusive of mixing layers, T_{RuSi} represents a thickness of a mixing layer at a boundary portion between the uppermost silicon (Si) layer and the protection film, and T_{Ru} represents a thickness of the protection film, and each thickness is a numerical value expressed in unit of “nm”.

Further, in each of the thicknesses of the Ru films, when the amount of decrease in the thickness of the uppermost Si layer varies within a range of ±0.1 nm, the reflectance varies in the low incident angle region. At an incident angle of 1.3°, it was found that the reflectance varies by about 0.5% as a difference with respect to the prescribed reflectance. Meanwhile, when the amount of decrease in the thickness of the uppermost Si layer varies within a range of ±0.2 nm, at an incident angle of 1.3°, the reflectance variation was increased to about 1% as a difference with respect to the prescribed reflectance. According to the above results, it was found that when an acceptable thickness variation is ±0.1 nm, a practical thickness range must satisfy the following expression (1):

5.3≤T_{upSi}+T_{RuSi}+T_{Ru}/2≤5.5 (1).

Further, when the amount of decrease in the thickness of the uppermost Si layer is defined as (T_{Si}−T_{upSi}), it was found that the following expression:

T_{Ru}/2−(T_{Si}−T_{upSi})=1.2

holds between the amount of decrease, and the thickness T_{Ru} of the Ru protection film. In this expression, T_{upSi} represents a thickness of the uppermost Si layer exclusive of mixing layers, and T_{Si} represents a thickness of the Si layer exclusive of the mixing layers, in the periodic laminated structure below the uppermost Si layer, and each thickness is a numerical value expressed in unit of “nm”.

Also in this relational expression, under considering the acceptable thickness variation of a range of ±0.1 nm, it was found that a practical thickness range must satisfy the following expression (2):

1.1≤T_{RU}/2−(T_{Si}−T_{upSi})≤1.3 (2).

According to the above designed values, it was found that a substrate with a film for a reflective mask blank having a high minimum reflectance of preferably at least 64%, more preferably at least 65%, even more preferably at least 66% in a range of an incident angle of from 1.3 to 10.7° can be realized by forming a Mo/Si multilayer reflection film (40 pairs) having a cycle length of 7.02 nm and a protection film consisting of a Ru film, on a substrate composed of a low thermal expansion material.

### Example for Embodiment 2

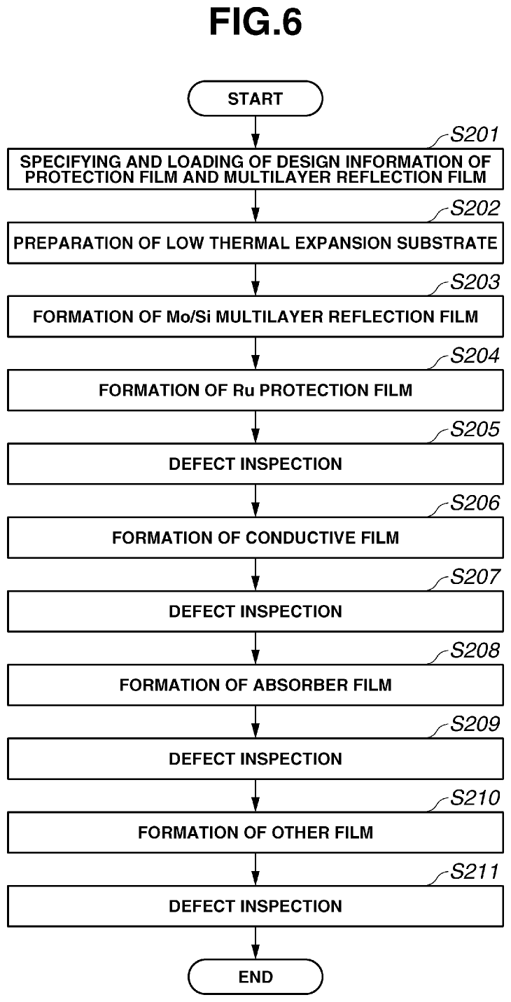

In this embodiment, a reflective mask blank was manufactured. An absorber film was formed on a protection film of a substrate with a reflective mask blank, and a conductive film was formed on another main surface (back side surface) which is opposite to the main surface on which the absorber film was formed. The manufacturing procedure is described with reference to FIG. 6.

First, design information for a basic structure such as a thickness in each layer of a protection film and a multilayer reflection film is specified and loaded (Step S201). Next, a substrate composed of a low thermal expansion material is prepared (Step S202). As the substrate, a substrate on which the front and back main surfaces have a prescribed surface roughness is prepared. Next, a Mo/Si (40 pairs) multilayer reflection film in which a Si layer is an uppermost layer, having a cycle length of 7.02 nm is formed on one of the main surfaces in accordance with the information for the basic structure (Step S203). In this regard, only the thickness of the uppermost Si layer is set to be 0.6 nm thinner than the thickness of the Si layer in a periodic laminated structure thereunder. Next, a protection film composed of Ru having a thickness of 3.5 nm is formed in Step S204. The multilayer reflection film and the protection film may be formed, respectively, by an ion beam sputtering method, a DC sputtering method or a RF sputtering method.

In Step S205, defects of the laminated films of the multilayer reflection film and the protection film are inspected, and defect location information and defect inspection signal information are saved into a recording medium. The defect to be inspected here is mainly phase defects which are involved in the multilayer reflection film, particles attached on the surface of the protection film, or the like.

Next, in Step S206, a conductive film is formed on the opposite surface (back surface) of the substrate composed of a low thermal expansion material, and defect inspection is performed in Step S207. The defect to be inspected in this defect inspection is mainly attached particles. The object of this inspection is to confirm that particle defects (size of about 1 μm or more) that deteriorate pattern transferability do not exist on the film when the formed reflective mask is electrostatically held on a mask stage of a pattern transfer tool.

In the defect inspection steps of Step S205 and Step S207, the substrate is cleaned or discarded when a critical defect is detected. On the other hand, the substrate is proceeded to next step when the defect is acceptable or no defect is detected. The step of forming the conductive film (Step S206) and the step of inspecting the conductive film (Step S207) may be performed prior to the step of forming the Mo/Si multilayer reflection film (Step S203).

In Step S208, an absorber film is formed on the protection film. The absorber film may also be formed by an ion beam sputtering method, a DC sputtering method or a RF sputtering method. After that, the surface of the absorber film is inspected for defects (Step S209).

According to the above method, the reflective mask blank having the basic structure is completed. If need, other film(s) may be formed (Step S210). Here, the other film(s) include a thin hard mask as a processing aid layer for the absorber film, and a resist film. When the other film(s) are formed, the film(s) are inspected for defects (Step S211), and finally, the reflective mask blank is completed.

By this embodiment, even when a protection film having a thickness of 3.0 to 4.0 nm is formed on a Mo/Si multilayer reflection film, an absorber film can be formed on the protection film of a substrate with a film for a reflective mask blank that can control decrease of reflectance of the multilayer reflection film. Accordingly, a highly reliable reflective mask blank in which a high reflectance is ensured in a prescribed range of an incident angle (1.3 to 10.7°) of EUV light with protecting the multilayer reflection film can be provided.

Japanese Patent Application No. 2020-79089 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A substrate with a film for a reflective mask blank comprising a substrate, a multilayer reflection film that is formed on a main surface of the substrate and reflects extreme ultraviolet (EUV) light, and a protection film thereon that is formed contiguous to the multilayer reflection film, wherein
the multilayer reflection film has a periodic laminated structure in which molybdenum (Mo) layers and silicon layers (Si) are alternately laminated with an uppermost silicon (Si) layer, and one mixing layer containing Mo and Si exists at one boundary portion between the molybdenum (Mo) layer and the silicon (Si) layer,
the protection film contains ruthenium (Ru) as a main component, and another mixing layer containing Ru and Si is generated at another boundary portion between the uppermost silicon (Si) layer and the protection film, and
thicknesses of the film and layers defined below satisfy all of the following expressions (1) to (3):
5.3≤T_{upSi}+T_{RuSi}+T_{Ru}/2≤5.5 (1)
1.1≤T_{Ru}/2−(T_{Si}−T_{upSi})≤1.3 (2)
3.0≤T_{Ru}≤4.0 (3)
wherein T_{Ru} (nm) represents a thickness of the protection film, T_{RuSi} (nm) represents a thickness of said another mixing layer at said another boundary portion between the uppermost silicon (Si) layer and the protection film, T_{upSi} (nm) represents a thickness of the uppermost silicon (Si) layer exclusive of the mixing layers, and T_{Si} (nm) represents a thickness of the silicon (Si) layer exclusive of the mixing layers, in the periodic laminated structure below the uppermost silicon (Si) layer.

2. The substrate with a film for a reflective mask blank of claim 1 wherein a minimum reflectance Rₘᵢₙ (%) with respect to EUV light at an incident angle in a range of 1.3 to 10.7° satisfies the following expression (4):
Rₘᵢₙ≥72−2×T_{Ru} (4)
wherein T_{Ru} represents a thickness (nm) of the protection film.

3. A reflective mask blank comprising the substrate with a film for a reflective mask blank of claim 1, an absorber film that is formed on the protection film and absorbs the extreme ultraviolet (EUV) light, and a conductive layer formed on the opposite main surface of the substrate.

4. A reflective mask blank comprising the substrate with a film for a reflective mask blank of claim 2, an absorber film that is formed on the protection film and absorbs the extreme ultraviolet (EUV) light, and a conductive layer formed on the opposite main surface of the substrate.
